(19) United States
(12) Patent Application Publication
(10) Pub. No.: US 2016/0049307 A1
(43) Pub. Date: Feb. 18, 2016

(54) Patterning method for IC fabrication using 2-D layout decomposition and synthesis techniques

(71) Applicant: Yijian Chen, Hercules, CA (US)

(72) Inventor: Yijian Chen, Hercules, CA (US)

(21) Appl. No.: 14/121,229

(22) Filed: Aug. 15, 2014

(51) Int. Cl. H01L 21/311; H01L 21/32; H01L 21/02; H01L 21/3105

(52) U.S. Cl. CPC H01L 21/31111; H01L 21/31051; H01L 21/32; H01L 21/02115; H01L 21/02164; H01L 21/0217

(57) ABSTRACT

Various multiple-mask patterning methods by employing the layout decomposition and stitching technique are invented. The inventions pertain to methods of decomposing and synthesizing two-dimensional features on a substrate having the feature density increased to multiple times (up to eight times) of what is possible using the standard optical lithographic technique; and methods to release the overlay requirement when patterning the critical layers of semiconductor devices. The invented processes allow IC designers to pattern random two-dimensional circuit features that are beyond the resolution capability of optical lithography. They provide production-worthy methods for the semiconductor industry to continue IC scaling beyond the half pitch of 10 nm.

### BACKGROUND OF THE INVENTION

Despite the significant progress made in next-generation lithography such as extreme ultraviolet (EUV, wavelength: 13.5 nm) technology, the challenges of its insertion into high-volume semiconductor manufacturing are non-trivial. Alternatively, the self-aligned multiple patterning (SAMP) or directed self-assembly (DSA) technique can be the potential solution to pattern dense 1-D structures of both memory and logic devices [1]. The main characteristic of spacer based SAMP processes is the consecutive sidewall-spacer steps following the so-called mandrel patterning to enable spatial frequency multiplication. The SAMP processes include double (SADP [2]), triple (SATP [3]), quadruple (SAQP [4-5]), sextuple (SASP [6]), octuple (SAOP [7]) schemes, as demonstrated in FIGS. 1-3 (prior arts). In a SAMP process, the mandrels are first patterned by optical lithography (i.e., the “mandrel” step) and the spacers are formed along the sidewalls of the mandrels (i.e., the “spacer” step). After removing the mandrels by a plasma etch process, the spacer patterns are transferred to a layer underneath by another plasma etch process and the resultant feature density becomes twice of the mandrel features. Some SAMP processes require the second spacers (as shown in FIG. 1) and the third spacers (as shown in FIGS. 2-3) to further increase the final feature density. The SAMP processes can be categorized into two types: positive-tone or negative-tone. In positive-tone SAMP processes, the final spacers remain to be the lines; while in negative-tone SAMP processes, the final spacers will be reversed to become trenches/spaces. Other promising candidates of patterning technology include the directed self-assembly (DSA) process, which is a cost-effective chemical frequency-multiplication technique using pre-patterned templates ([8-11]) and does not require consecutive spacer steps.

When combined with ArF DUV (193 nm) immersion lithography (half-pitch resolution: about 38 nm), DSA and SAMP techniques can potentially drive the half pitch of IC features down to sub-10 nm. By designing various template/mandrel shapes which further define the route of the spacer lines around them, DSA and SAMP techniques do offer certain types of 2-D patterning freedom. However, the geometric constraints due to the closed-loop spacers around the mandrels seriously limit the random 2-D patterning flexibility of SAMP processes [12-13]. DSA also suffers from the unpredictable defect window issue [1]. In general, 2-mask (template/mandrel mask and cut mask) DSA and SAMP process cannot meet the random 2-D patterning requirements unless the IC device structure and related layout design are dramatically changed. Although 2-D patterning capability for the half pitch of 19-13 nm may be possible by the optical triple patterning (TP [14]), an extension of the TP technique to the optical quadruple patterning (QP) for sub-13 nm half pitch is difficult due to the prohibitive barriers of overlay limit and process control. Consequently, there is an urgent need to explore other practical 2-D patterning solutions (based on the SAMP or DSA processes) with relaxed overlay requirements to avoid a serious slowdown of Moore's Law in the sub-13 nm era.

Both SAMP and DSA processes are suitable for patterning 1-D (or uni-directional) features. For example, 2-mask (template/mandrel mask and cut mask) SAQP processes have been proposed for 1-D patterning [12-13]. Depending on how many masks are required, SAMP layout decomposition is not as intuitive as optical multiple patterning (e.g., TP). It needs to deal with the complicated interaction between the mandrels and spacers, and possibly extra mask(s) to introduce more 2-D design freedom. Mathematically, SAMP layout decomposition can be transformed into a graph coloring problem. Nevertheless, 3-coloring problem in graph theory is a NP-complete problem [15] and an efficient full-chip layout decomposition algorithm for SAMP processes is extremely difficult. 2-D DSA layout decomposition is also on the early stage of concept development and no mature results have been reported yet. Therefore, a standalone SAMP/DSA process is incapable of random 2-D patterning. Our goal is to develop an efficient method to decompose a random 2-D IC layout into several manageable levels that can be patterned separately by SAMP/DSA processes and recombined together to recover the original layout features. This would be different from the conventional (optical) multiple patterning (MP [1]) since each decomposed layer in MP processes requires only one lithography step and no SAMP/DSA process is used for any MP layer.

### BRIEF SUMMARY OF THE INVENTION

Embodiments of the present invention pertain to methods of decomposing and synthesizing random 2-D layout features on a substrate using specific masks and methods, resulting in a final pitch reduced to one fourth (using SAQP process), one sixth (using SASP process), or one eighth (using SAOP process) of the original pitch defined by the resolution limit of lithography. Based on the standard semiconductor fabrication processes, a multiple-mask patterning technology by employing the invented layout decomposition and stitching techniques is developed to pattern random 2-D patterns and to relax the overlay requirements. In this technology, a random 2-D IC layout is first decomposed into several sets of 1-D patterns. SAMP or DSA process is separately applied to pattern each set of 1-D patterns which are uni-directionally oriented. These patterns contain high-density parallel lines which are first formed with one “mandrel” mask, followed by one or multiple “cut” steps to remove the unwanted parts and form shorter line segments.

As shown in FIG. 4, forming 1-D line/space patterns followed by “cuts” is known as “complementary” lithography which is often adopted for 1-D gridded design in the semiconductor industry [1, 16, 17]. It usually requires multiple “via” processes to connect the decomposed 1-D patterns (e.g., metals) at different levels [17]. It should be reminded that neither SAMP/DSA processes nor 1-D “complementary” lithography is claimed as our invention. Our patent claims are focused on the specific layout decomposition and stitching techniques to form random 2-D features with relaxed overlay requirement. Our invention not only allows a direct stitching of the decomposed multiple sets of 1-D patterns (oriented in different directions), but also helps to remove the multiple via processing steps that would be otherwise required to connect the 1-D patterns at different levels (e.g., in 1-D gridded design).

A layout example in FIG. 5 is used to show how a random 2-D layout is decomposed into two sets of 1-D patterns by a suitable layout decomposition algorithm. The first set of 1-D dense line/space patterns will be formed by a SAMP or DSA process (using the “mandrel 1” mask which is the first mask) followed by one or multiple cut steps (using one or multiple “cut” masks) to trim the lines/spaces into useful patterns (e.g., shorter line/space segments). The idea of “stitching” is shown in FIG. 6. The stitching process consists of a series of etching, planarization, and thin-film deposition steps. A plasma etch process will be applied to transfer the first set of 1-D patterns to underneath layer. A thin-film process (either chemical vapor deposition or spin-on coating) will be performed to cover the formed 1-D patterns, possibly followed by a chemical mechanical polishing (CMP) step to planarize the wafer surface. This thin-film (coating) material should be different than the material of the first 1-D patterns and has high etch selectivity between them in the following etch processes. After these steps, the second set of 1-D patterns will be similarly formed and transferred to underneath by a plasma etch process. While etching to transfer the second set of 1-D features (i.e., stitching step), the first set of 1-D patterns should not be attacked such that both of them finally will be merged together to form continuous 2-D patterns at the same level (with no need of vias to connect them).

The above process is quasi-self-aligned and the only step that requires certain overlay accuracy is the “stitching” step. Compared with the multiple via steps that all require high overlay accuracy in 1-D gridded design, our process can significantly release the overlay requirement. Moreover, only one stitching step is required in our process and the single-stitching yield is also higher than that of optical multiple patterning (e.g., TP or QP) techniques which require multiple stitching steps. Namely, the SAMP/DSA process to form each set of 1-D patterns is self-aligned and only one single stitching step is not self-aligned. This is one major innovation/advantage (besides the random 2-D patterning and frequency multiplication capabilities) of the invented process. It allows IC designers to efficiently decompose and synthesize the random 2-D layout features that are beyond the resolution capability of optical lithography.

It should be pointed out that the directions of decomposed 1-D patterns shown in FIGS. 5 and 6, and the specific process examples/materials are for the purposes of illustration only and are not intended to limit the scope of this disclosure. For instance, the number of cut masks can be either one or multiple, and the decomposed 1-D patterns can be oriented into two orthogonal or several arbitrary (different) directions.

### BRIEF DESCRIPTION OF THE SEVERAL VIEWS OF THE DRAWING(S)

A further understanding of the nature and advantages of the invention may be realized by reference to the specification and the drawings presented below. The figures are incorporated into the detailed description portion of the invention.

FIG. 1, a figure of representing prior art, depicts a self-aligned quadruple patterning (SAQP [5]) process flow which can reduce the half pitch of the final circuit patterns by a factor of four from what is available by conventional lithography.

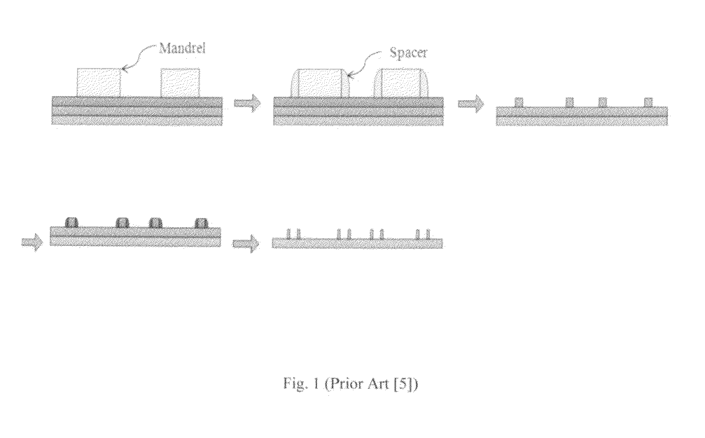

FIG. 2, a figure of representing prior art, depicts a self-aligned sextuple patterning (SASP [6]) process flow which can reduce the minimum half pitch of final circuit patterns by a factor of six from what is available by conventional lithography.

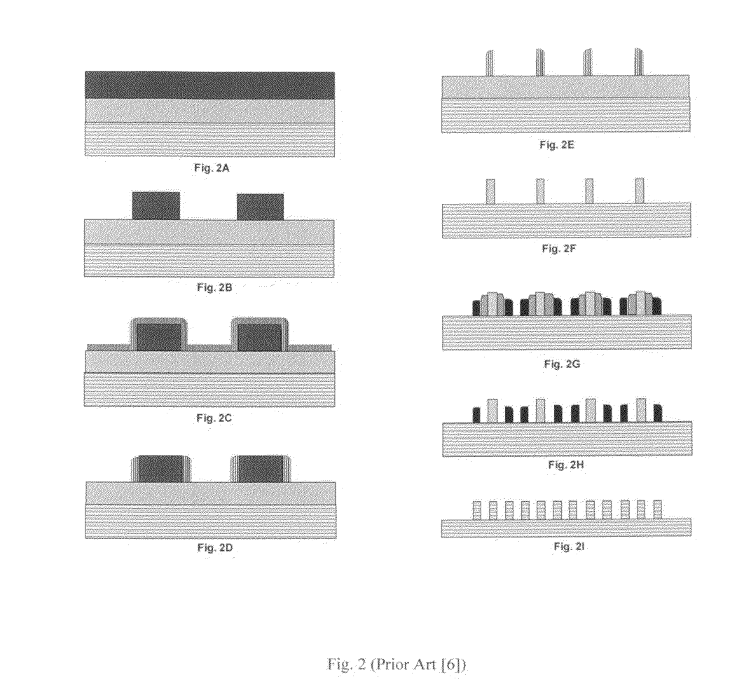

FIG. 3, a figure of representing prior art, depicts a self-aligned octuple patterning (SAOP [7]) process flow which can reduce the minimum half pitch of final circuit patterns by a factor of eight from what is available by conventional lithography.

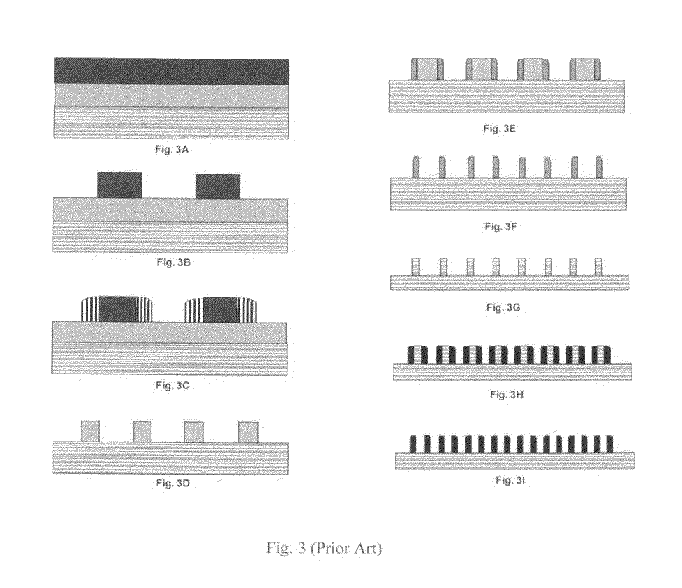

FIG. 4, a figure of representing prior art, illustrates the concept of complementary lithography wherein the high-density horizontal lines/spaces are formed with a self-aligned multiple patterning (SAMP) or directed self-assembly (DSA) process, while one or multiple cut steps are applied to remove the unwanted parts to form the desired 1-D patterns (the right-side structures).

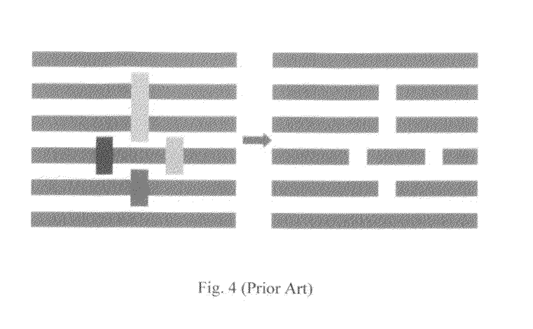

FIG. 5 is an example to illuminate the top views of the layout decomposition process wherein a random 2-D IC layout (shown in FIG. 5A) is decomposed into two sets of 1-D patterns in X and Y directions, both of which are separately formed by a SAMP process and cut step(s) using one or multiple cut masks (i.e., complementary lithography shown in FIG. 4).

FIG. 6 is an example to illuminate the top view's of the layout synthesis/stitching process wherein the 1-D patterns (in X and Y directions) shown in FIG. 6A and FIG. 6B (or in FIG. 5B and FIG. 5C) are recombined together to recover the original 2-D patterns at the same level as shown in FIG. 6C (or in FIG. 5A).

FIG. 7 is a flowchart depicting steps associated with the SAQP based process shown in FIG. 8.

FIG. 8 depicts a SAQP based process to form uni-directional 1-D patterns.

### DETAILED DESCRIPTION OF THE INVENTION

A number of novel layout decomposition and stitching techniques are developed in accordance with the invention. In one such process, random 2-D layout features are decomposed into two sets of features: one set of 1-D features arranged in one direction (defined to be X direction) and the other set of 1-D features arranged in the other direction (defined to be Y direction). In general, X and Y directions can be arbitrary and not necessarily orthogonal. These two sets of 1-D patterns are each separately formed by certain SAMP process (e.g., SAQP, SASP, or SAOP Process) using multiple masks (i.e., one mandrel mask and one/multiple cut masks). The type of SAMP process and the mask number to form the X-direction 1-D patterns, do not have to be the same as those to form Y-direction 1-D patterns.

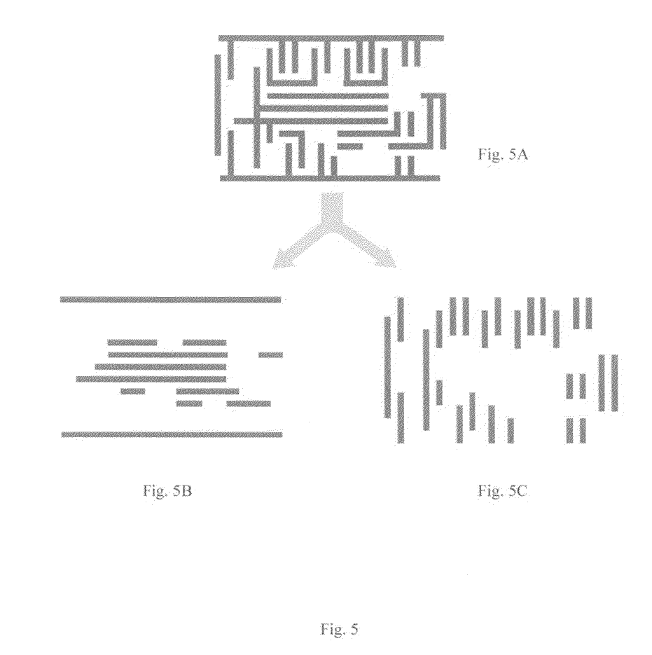

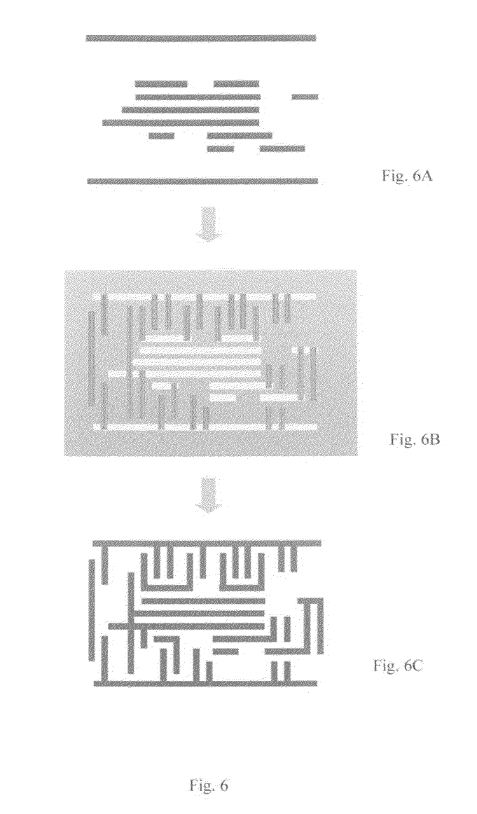

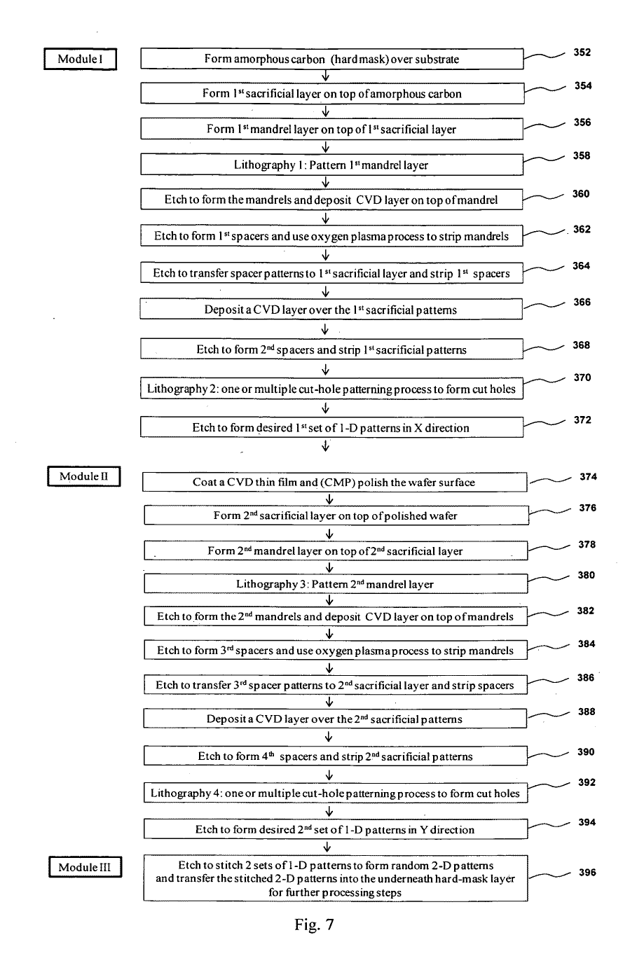

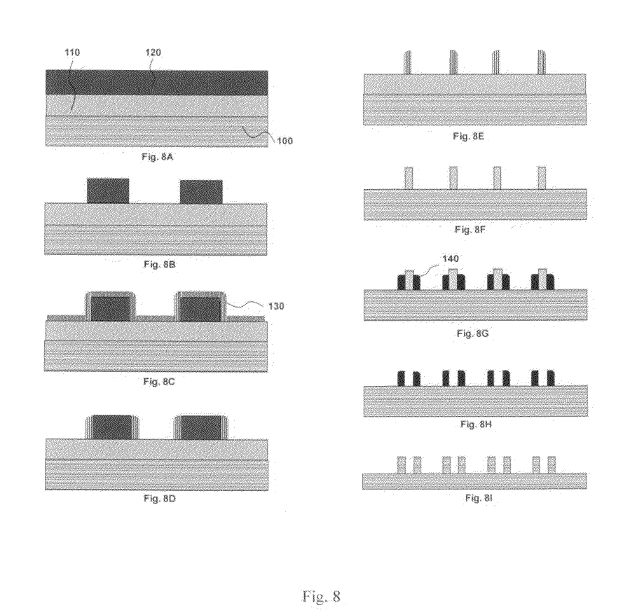

To better understand and appreciate the invention, a flowchart is shown in FIG. 7 to depict the steps associated with a self-aligned quadruple patterning (SAQP) process according to one embodiment of the invention. The correspondingly cross-sectional views cutting through the array structure (lines/spaces) is shown FIG. 8 to illustrate the process details in the above flowchart. The method starts from Module I by forming a stack of layers on the wafer substrate as shown in FIG. 8, and indicated in operations 352, 354 and 356 as shown in FIG. 7. This stack of layers includes a hard-mask layer 100 and the first sacrificial layer 110, and the first mandrel layer 120. The sacrificial layer can be other commonly used semiconductor material that can be dry etched by a highly selective plasma process or wet etched by a selective chemical solution. The possible choices of the sacrificial material include (but not limited to): amorphous carbon (normally requiring a thin protective nitride layer on the top) which can be etched by oxygen plasma, photo-sensitive imaging materials such as a combination of photoresist and BARC (bottom anti-reflective coating, which is usually required before photoresist coating to reduce the standing-wave effect) that can also be etched by oxygen plasma, silicon oxide that can be wet etched by HF solution, silicon nitride that can be wet etched by phosphoric acid, or polycrystalline Si (poly-Si) that can be wet etched by KOH solution. The first mandrel layer 120 is patterned by the optical lithography 1 (operation 358) and the half pitch of patterned features is defined by the minimum resolution of the lithographic tools (e.g., about 38 nm in ArF DUV immersion lithography). The formed patterns on resist is transferred to the first mandrel layer, as shown in FIG. 8B and depicted by operation 360. A CVD (chemical vapor deposition) layer 130 is then deposited on top of the first mandrel patterns and etched back to form spacers on the sidewalls of the mandrels, as shown in FIG. 8D. The first mandrel structures are then stripped by an oxygen plasma process (operation 362), resulting in spatial frequency doubling of the first spacer features as shown in FIG. 8E. The formed spacer patterns are transferred to the first sacrificial layer by a plasma etching process, and the spacers are stripped (operation 364), as shown in FIG. 8F. Another CVD layer is then deposited (operation 366) on top of the first sacrificial patterns and etched back to form the second spacers 140 on the sidewalls of the sacrificial structures, as shown in FIG. 8G. The first sacrificial structures are then stripped by an oxygen plasma process (operation 368), resulting in spatial frequency quadrupling as shown in FIG. 8H. One or multiple lithography steps will form cut holes (operation 370: Lithography 2) followed by etching step(s) to cut the second spacers to form the desired 1-D patterns. After this step, the second spacer patterns (in X direction), as shown in the top views of FIGS. 5B and 6A, are transferred to the underneath hard-mask layer (operation 372), as shown in FIG. 8I.

The second module (Module II) consists of a series of processing steps similar to those of Module I, except that a gap-fill layer is needed to completely fill the gaps/trenches formed in Module I and a chemical mechanical polishing (CMP) process to planarize the surface of the gap-fill layer is required to create a flat surface (to ensure a satisfactory performance of the following lithography process). Operations 374-394 in the flowchart of FIG. 7 depict the steps associated with Module II. The correspondingly cross-sectional views cutting through the array structure are similar to FIG. 8 except that they are oriented in Y direction, as shown in the top views of FIGS. 5C and 6B.

After the 1-D patterns in Y direction are formed in Module II, the stitching step (operation 396) is achieved by a selective etching process which transfers the 1-D patterns in Y direction to overlap the previously formed 1-D patterns in X direction to create the desired 2-D patterns in the hard-mask layer, as shown in the top views of FIG. 6C. These 2-D patterns in the hard-mask can then be employed in the following processing steps.

The uniqueness of the invention is first: the design of a process that can combine the advantages of SAMP/DSA and double patterning (stitching) processes in a practical manner to form random 2-D patterns. The resultant process costs slightly increase while its feature density is higher than achievable with a pure (optical) double/triple patterning process and the 2-D design flexibility is improved than a pure SAMP/DSA process. Secondly, it only requires one stitching step, which helps to release the overlay requirement and increase the process yield.

1. A SAQP process based IC patterning method which consists of three key process modules:
Module I (the first module to form high-density 1-D patterns in X direction) which comprises
a (first) hard-mask layer formed over the substrate;
a (first) sacrificial layer formed over the first hard-mask layer;
a (first) mandrel layer formed over the first sacrificial stack;
a lithographic step to pattern the resist coated on wafer;
etching the first mandrel layer to form the first mandrel lines;
deposition of a CVD layer over the first mandrel features;
etching the CVD layer to form spacers on the sidewall of the first mandrel features;
etching/stripping the first mandrel layer to form the first spacers;
etching to transfer the first spacers to the first sacrificial layer underneath and stripping the first spacers;
deposition of a CVD layer over the first sacrificial features;
etching the CVD layer to form the second spacers on the sidewall of the first sacrificial features;
etching/stripping the first sacrificial layer to form the second spacers;
one or multiple lithographic and etching step(s) to cut the second spacers to form the desired 1-D patterns in X direction;
etching to transfer the cut spacer patterns to the hard-mask layer underneath;
Module II (the second module to form high-density 1-D patterns in Y direction) which comprises
forming the gap-fill layer over the 1-D patterns to completely fill the gaps/trenches;
a chemical mechanical polishing (CMP) process to planarize the wafer surface;
forming the second sacrificial layer;
forming the second mandrel layer;
a lithographic step to pattern the resist (in the orthogonal direction) coated on the second mandrel layer;
etching the second mandrel layer to form the second mandrel lines;
deposition of a CVD layer over the second mandrel features;
etching the CVD layer to form spacers on the sidewall of the second mandrel features;
etching/stripping the second mandrel layer to form the third spacers;
etching to transfer the third spacers to the second sacrificial layer underneath and stripping the third spacers;
deposition of a CVD layer over the second sacrificial features;
etching the CVD layer to form the fourth spacers on the sidewall of the second sacrificial features;
etching/stripping the second sacrificial layer to form the fourth spacers;
one or multiple lithographic and etching step(s) to cut the fourth spacers to form desired 1-D patterns (in Y direction);
Module III (the third module to stitch two sets of 1-D patterns to form random 2-D patterns) which comprises
etching to transfer the 1-D patterns in the orthogonal direction to the substrate and to recombine them with the first 1-D patterns to form 2-D patterns (i.e., stitching step);
final etching step to transfer the 2-D patterns to the hard-mask layer for continuous processing.

2. The method of claim 1 wherein the mandrel materials are all amorphous carbon.

3. The method of claim 1 wherein the mandrel materials comprise a stack of resist and BARC.

4. The method of claim 1 wherein the sacrificial materials comprise a stack of silicon oxide (top) and amorphous carbon (bottom).

5. The method of claim 1 wherein the sacrificial materials comprise a stack of silicon nitride (top) and amorphous carbon (bottom).

6. The method of claim 1 wherein the CVD material deposited over the mandrel features is silicon oxide.

7. The method of claim 1 wherein the CVD material deposited over the mandrel features is silicon nitride.

8. The method of claim 1 wherein the sacrificial feature is patterned resist and the CVD material deposited over the sacrificial features is low-temperature (lower than 300° C.) silicon oxide (to avoid the harmful reaction between resist and CVD material).

9. The method of claim 1 wherein the spacers formed on the sidewall of sacrificial layer are polycrystalline (or amorphous) silicon.

10. The method of claim 1 wherein the spacers formed on the sidewall of sacrificial layer are silicon oxide.

11. The method of claim 1 wherein the spacers formed on the sidewall of sacrificial layer are silicon nitride.

12. The method of claim 1 wherein the SAQP process is replaced by the SASP process.

13. The method of claim 1 wherein the SAQP process is replaced by the SAOP process.

14. The method of claim 1 wherein the SAQP process is replaced by a DSA process.
